(19) United States
(12) Patent Application Publication
(10) Pub. No.: US 2026/0074680 A1
(43) Pub. Date: Mar. 12, 2026

(54) High-Side Switch System, Method for Controlling the Same, Integrated Circuit Chip, and Electronic Device

(71) Applicant: Halo Microelectronics (Beijing) Ltd., Beijing (CN)

(72) Inventors: Wenchao Qu, Chengdu (CN); Muhammad Ahmed, Garland, TX (US)

(21) Appl. No.: 19/034,548

(22) Filed: Jan. 22, 2025

(30) Foreign Application Priority Data
Sep. 6, 2024 (CN) 2024112522203

(51) Int. Cl. H03K 3/012; H03K 17/687

(52) U.S. Cl. CPC H03K 3/012; H03K 17/687; H03K 2217/0063

(57) ABSTRACT

A high-side switch system includes a switch transistor, a reversed power supply protection circuit, and an input voltage bus. The reversed power supply protection circuit is configured to, in response to receiving a voltage at a third terminal of the reversed power supply protection circuit when a positive terminal of a power supply is connected to a ground and a negative terminal of the power supply is connected to the input voltage bus, establish a current path from the third terminal to a first terminal of the reversed power supply protection circuit, which provides current to turn on the switch transistor. The reversed power supply protection circuit is configured to disconnect the current path when the positive terminal of the power supply is connected to the input voltage bus and the negative terminal of the power supply is connected to the ground. A control method is also provided.

### CROSS-REFERENCE TO RELATED APPLICATIONS

This application claims priority to Chinese Patent Application No. 202411252220.3, filed on Sep. 6, 2024, and entitled “High-side System, Control Method, Chip and Electronic Device,” which is hereby incorporated by reference in its entirety.

### TECHNICAL FIELD

Embodiments of this application relate to the technical field of electronic circuits, and more specifically, to a high-side switch system, its control method, an integrated circuit chip, and an electronic device.

### BACKGROUND

For devices equipped with integrated circuit chips (such as automotive integrated circuit chips), a common issue in practical applications is that improper use by a user, such as reversing the power supply polarity, can cause damage to electronic components in a device.

For high-side switch integrated circuit chips, when an integrated circuit chip is connected to a load, the source terminal of a high-side switch is connected to the load, and the drain terminal of the high-side switch is connected to an input voltage bus. When the power supply polarity is reversed (i.e. the positive terminal of the power supply is connected to the system ground and the negative terminal of the power supply is connected to the input voltage bus), current flows from the positive terminal of the power supply into the system ground, passes through the load and the body diode of the high-side switch to the input voltage bus, and then flows into the negative terminal of the power supply, thus forming a current path. However, due to the low internal resistance of the load and the body diode of the high-side switch generating at least a 0.7V voltage drop, the power loss on the body diode of the high-side switch can be significant. Excessive power loss can cause the high-side switch to overheat and become damaged.

### SUMMARY

Embodiments of this application provide a high-side switch system, its control method, an integrated circuit chip, and an electronic device, which can reduce the risk of damage to the high-side switch.

In a first aspect, the embodiments of this application provide a high-side switch system, comprising: a first switch transistor, a load, a reversed power supply protection circuit, and an input voltage bus. A first terminal of the first switch transistor is connected to a first terminal of the reversed power supply protection circuit, and a second terminal of the first switch transistor is connected to a first terminal of the load at a voltage output terminal of the high-side switch system. A third terminal of the first switch transistor and a second terminal of the reversed power supply protection circuit are both connected to the input voltage bus, and a second terminal of the load is connected to a first ground. The reversed power supply protection circuit is configured to receive a first voltage at a third terminal of the reversed power supply protection circuit when a positive terminal of a power supply is connected to the first ground and a negative terminal of the power supply is connected to the input voltage bus, and to conduct a current path from the third terminal to the first terminal of the reversed power supply protection circuit in response to the first voltage, thereby providing current through this path to the first terminal of the first switch transistor to drive the first switch transistor to turn on. The reversed power supply protection circuit is further configured to disconnect the current path when the positive terminal of the power supply is connected to the input voltage bus and the negative terminal of the power supply is connected to the first ground.

In one or more embodiments, the third terminal of the reversed power supply protection circuit is connected to the first ground, wherein, when the positive terminal of the power supply is connected to the first ground and the negative terminal of the power supply is connected to the input voltage bus, the first voltage is equal to a voltage of the power supply.

In one or more embodiments, the high-side switch system further comprises an external circuit, wherein a first terminal of the external circuit is connected to the third terminal of the reversed power supply protection circuit, and a second terminal of the external circuit is connected to the first ground. The external circuit is configured to output the first voltage to the third terminal of the reversed power supply protection circuit based on the voltage of the power supply when the positive terminal of the power supply is connected to the first ground and the negative terminal of the power supply is connected to the input voltage bus.

In one or more embodiments, the external circuit comprises a first diode, wherein the anode of the first diode is connected to the first ground and the cathode of the first diode is connected to the first terminal of the external circuit. When the positive terminal of the power supply is connected to the first ground and the negative terminal of the power supply is connected to the input voltage bus, the first voltage equals a difference between the voltage of the power supply and the forward voltage drop of the first diode.

In one or more embodiments, the reversed power supply protection circuit comprises a second switch transistor, a first Zener diode, a second diode, and a first resistor. The first resistor is connected between an anode of the second diode and the first ground, a cathode of the second diode is connected to a cathode of the first Zener diode and a second terminal of the second switch transistor, a first terminal of the second switch transistor and an anode of the first Zener diode are both connected to the input voltage bus, and a third terminal of the second switch transistor is connected to the first terminal of the reversed power supply protection circuit.

In one or more embodiments, the reversed power supply protection circuit further comprises a third switch transistor and a third diode connected between the cathode of the first Zener diode and the second terminal of the second switch transistor, wherein the second diode is a body diode of the third switch transistor. A first terminal of the third switch transistor is connected to the input voltage bus, a second terminal of the third switch transistor is connected to the cathode of the first Zener diode and an anode of the third diode, a third terminal of the third switch transistor is connected to the first resistor, and a cathode of the third diode is connected to the second terminal of the second switch transistor.

In one or more embodiments, the first switch transistor and the reversed power supply protection circuit are integrated within a single integrated circuit chip, and the substrate of the integrated circuit chip is a second ground.

In one or more embodiments, the high-side switch system further comprises a first Schottky diode. An anode of the first Schottky diode is connected to the voltage output terminal of the high-side switch system, and the cathode of the first Schottky diode is connected to the input voltage bus.

In one or more embodiments, the high-side switch system further comprises a second Schottky diode. An anode of the second Schottky diode is connected to the second ground, and a cathode of the second Schottky diode is connected to the input voltage bus.

In one or more embodiments, the high-side switch system further comprises a switch circuit connected between the input voltage bus and the second ground. The switch circuit is configured to turn on to short the input voltage bus to the second ground when the positive terminal of the power supply is connected to the first ground and the negative terminal of the power supply is connected to the input voltage bus. The switch circuit is further configured to disconnect to stop shorting the input voltage bus to the second ground when the positive terminal of the power supply is connected to the input voltage bus and the negative terminal of the power supply is connected to the first ground.

In one or more embodiments, the switch circuit comprises a fourth switch transistor. A first terminal of the fourth switch transistor is connected to the third terminal of the reversed power supply protection circuit, a third terminal of the fourth switch transistor is connected to the input voltage bus, and a second terminal of the fourth switch transistor is connected to the second ground.

In one or more embodiments, the switch circuit further comprises a second Zener diode, a third resistor, and a fourth resistor. An anode of the second Zener diode and a first terminal of the third resistor are both connected to the second ground. A cathode of the second Zener diode is connected to a second terminal of the third resistor, a first terminal of the fourth resistor and the first terminal of the fourth switch transistor. A second terminal of the fourth resistor is connected to the third terminal of the reversed power supply protection circuit.

In one or more embodiments, the switch circuit further comprises a fifth switch transistor, a sixth switch transistor, a third Zener diode, a fifth resistor, a sixth resistor and a seventh resistor. A third terminal of the fifth switch transistor is connected to the first terminal of the fourth resistor and the first terminal of the fourth switch transistor. A second terminal of the fifth switch transistor, a first terminal of the fifth resistor, and an anode of the third Zener diode are all connected to the second ground. A cathode of the third Zener diode is connected to the second terminal of the fifth resistor, a second terminal of the sixth switch transistor and a first terminal of the fifth switch transistor. A first terminal of the sixth switch transistor is connected to the second terminal of the fourth resistor and a second terminal of the seventh resistor. A third terminal of the sixth switch transistor is connected to a second terminal of the sixth resistor. A first terminal of the seventh resistor is connected to the third terminal of the reversed power supply protection circuit, while a first terminal of the sixth resistor is connected to the input voltage bus.

In one or more embodiments, the high-side switch system further comprises a grounding network, where a first terminal of the grounding network is connected to the first ground and a second terminal of the grounding network is connected to the second ground. The grounding network comprises a fourth diode and an eighth resistor, with a cathode of the fourth diode and a first terminal of the eighth resistor both connected to the first terminal of the grounding network, while an anode of the fourth diode and a second terminal of the eighth resistor are both connected to the second terminal of the grounding network.

According to a second aspect, the present application provides a control method of the high-side switch system. The high-side switch system comprising: a first switch transistor connected between an input voltage bus and a voltage output terminal of the high-side switch system, a load connected between the voltage output terminal of the high-side switch system and a first ground, and a reversed power supply protection circuit. A first terminal of the reversed power supply protection circuit is connected to the a first terminal of the first switch transistor. A second terminal of the reversed power supply protection circuit is connected to the input voltage bus. The method includes: when a positive terminal of a power supply is connected to the first ground and a negative terminal of the power supply is connected to the input voltage bus, a third terminal of the reversed power supply protection circuit is configured to receive a first voltage, allowing current to flow from the third terminal of the reversed power supply protection circuit to the first terminal of the reversed power supply protection circuit, where this current path provides current to the first terminal of the first switch transistor to turn on the first switch transistor. When the positive terminal of the power supply is connected to the input voltage bus and the negative terminal of the power supply is connected to the first ground, the current path is disconnected.

In one or more embodiments, the third terminal of the reversed power supply protection circuit is connected to the first ground; wherein, when the positive terminal of the power supply is connected to the first ground and the negative terminal of the power supply is connected to the input voltage bus, the first voltage equals the voltage of the power supply.

In one or more embodiments, the high-side switch system further comprises an external circuit, where a first terminal of the external circuit is connected to the third terminal of the reversed power supply protection circuit and a second terminal of the external circuit is connected to the first ground. The external circuit comprises a first diode, wherein an anode of the first diode is connected to the first ground and a cathode of the first diode is connected to the first terminal of the external circuit. When the positive terminal of the power supply is connected to the first ground and the negative terminal of the power supply is connected to the input voltage bus, the first voltage equals a difference between the voltage of the power supply and a forward voltage drop of the first diode.

In one or more embodiments, the first switch transistor and the reversed power supply protection circuit are integrated onto a single integrated circuit chip, with a substrate of the integrated circuit chip connected to a second ground. The high-side switch system further comprises a grounding network and a switch circuit, wherein the grounding network is connected between the first ground and the second ground, and the switch circuit is connected between the input voltage bus and the second ground. The grounding network comprises a fourth diode and an eighth resistor, with a cathode of the fourth diode and a first terminal of the eighth resistor both connected to the first ground, and an anode of the fourth diode and a second terminal of the eighth resistor are both connected to the second ground. The method further comprises: when the positive terminal of the power supply is connected to the first ground and the negative terminal of the power supply is connected to the input voltage bus, the switch circuit is turned on to short-circuit the input voltage bus to the second ground. When the positive terminal of the power supply is connected to the input voltage bus and the negative terminal of the power supply is connected to the first ground, the switch circuit is turned off.

A third aspect of the present application provides an integrated circuit chip that comprises the first switch transistor and the reversed power supply protection circuit as described above in the high-side switch system.

A fourth aspect of the present application provides an electronic device that comprises the integrated circuit chip as described above.

The beneficial effects of the present application are: the high-side switch system of the present embodiment comprises a first switch transistor, a load, a reversed power supply protection circuit, and an input voltage bus. When the positive terminal of the power supply is connected to the first ground and the negative terminal of the power supply is connected to the input voltage bus, which corresponds to reverse polarity of the power supply, the third terminal of the reversed power supply protection circuit receives the first voltage. In response to the first voltage, the current path from the third terminal to the first terminal of the reversed power supply protection circuit is turned on, thereby providing current to the first terminal of the first switch transistor to turn the first switch transistor on. As such, reverse current from the first ground to the input voltage bus will not flow through the body diode of the first switch transistor, instead, the reverse current will primarily pass through the first switch transistor in on-state. Since the equivalent resistance of the first switch transistor is low when it is turned on, there is minimal heat generated in the first switch transistor when carrying the reverse current, thus protecting the first switch transistor under reverse polarity conditions and reducing the risk of damage to the first switch transistor (corresponding to the high-side switch). Furthermore, when the positive terminal of the power supply is connected to the input voltage bus and the negative terminal of the power supply is connected to the first ground, i.e., under normal conditions, the reversed power supply protection circuit disconnects the current path, thereby not affecting the normal operation of the first switch transistor.

### BRIEF DESCRIPTION OF THE DRAWINGS

One or more embodiments are illustrated exemplarily by the images in the accompanying drawings, and these exemplary illustrations are not intended to limit the embodiments. Elements in the drawings having the same reference numerals denote similar elements.

FIG. 1 is a schematic diagram of a high-side switch system provided by embodiments of the present application;

FIG. 2 is a schematic diagram of another high-side switch system provided by embodiments of the present application;

FIG. 3 is a schematic diagram of another high-side switch system provided by embodiments of the present application;

FIG. 4 is a schematic diagram of a high-side switch system provided by embodiments of the present application;

FIG. 5 is a schematic diagram of a high-side switch system provided by embodiments of the present application;

FIG. 6 is a schematic diagram of a circuit structure of a high-side switch system provided by embodiments of the present application;

FIG. 7 is a schematic diagram of a circuit structure of a high-side switch system provided by embodiments of the present application;

FIG. 8 is a schematic diagram of a circuit structure of a high-side switch system provided by embodiments of the present application;

FIG. 9 is a schematic diagram of a circuit structure of a high-side switch system provided by embodiments of the present application;

FIG. 10 is a schematic diagram of a circuit structure of a high-side switch system provided by embodiments of the present application;

FIG. 11 is a schematic diagram of a circuit structure of a high-side switch system provided by embodiments of the present application;

FIG. 12 is a schematic diagram of a circuit structure of a high-side switch system provided by embodiments of the present application;

FIG. 13 is a schematic diagram of a circuit structure of a high-side switch system provided by embodiments of the present application;

FIG. 14 is a schematic diagram of a circuit structure of a high-side switch system provided by embodiments of the present application; and

FIG. 15 is a flowchart of a control method of a high-side switch system provided by embodiments of the present application.

### DETAILED DESCRIPTION OF ILLUSTRATIVE EMBODIMENTS

To clarify the objectives, technical solutions, and advantages of embodiments of the present application, a detailed description of the technical solutions in the embodiments of the present application will be provided in conjunction with the accompanying drawings. It is evident that the described embodiments are part of the embodiments of the present application and not all of the embodiments. It should be understood that the specific embodiments described here are intended to explain the present application and are not meant to limit the present application.

It should be noted that when an element is described as being “connected” to another element, the element can be directly connected to another element, or there may be one or more intermediate elements present.

Furthermore, the various technical features involved in the embodiments of the present application described below can be combined with each other, as long as there are no structural conflicts among them.

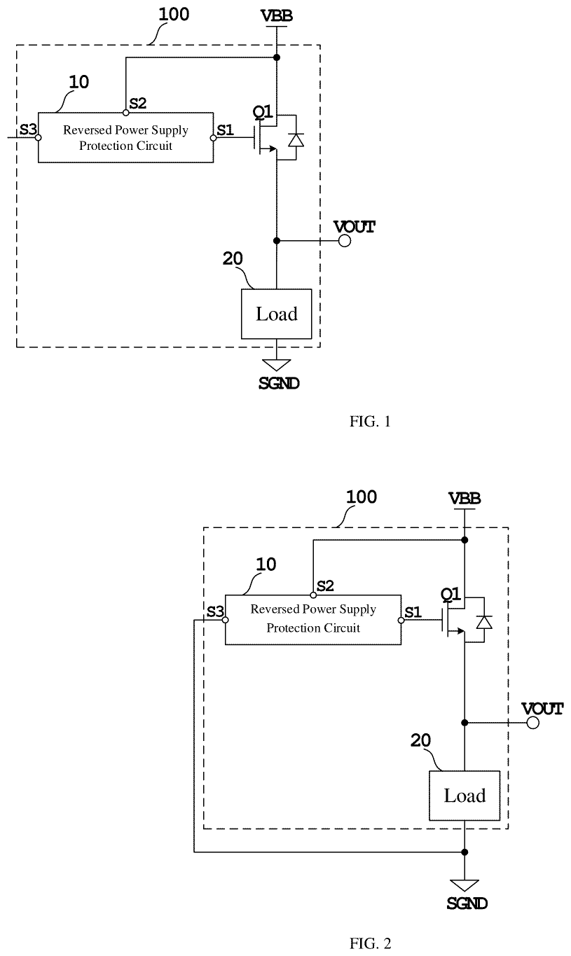

Referring to FIG. 1, FIG. 1 is a schematic diagram of a high-side switch system 100 provided by embodiments of the present application. As shown in FIG. 1, the high-side switch system 100 comprises a first switch transistor Q1, a load 20, a reversed power supply protection circuit 10, and an input voltage bus VBB. It can be understood that in the embodiments of the present application, the first switch transistor Q1 corresponds to the high-side switch of the high-side switch system 100.

A first terminal of the first switch transistor Q1 is connected to a first terminal S1 of the reversed power supply protection circuit 10. A second terminal of the first switch transistor Q1 is connected to a first terminal of the load 20 at a voltage output terminal VOUT of the high-side switch system 100. A third terminal of the first switch transistor Q1 and a second terminal S2 of the reversed power supply protection circuit 10 are both connected to an input voltage bus VBB. A second terminal of the load 20 is connected to a first ground SGND.

Specifically, when a positive terminal of a power supply (such as a battery) is connected to the first ground SGND and a negative terminal of the power supply is connected to the input voltage bus VBB, which indicates that the power supply is connected in reverse, a third terminal S3 of the reversed power supply protection circuit 10 receives a first voltage. At the same time, the reversed power supply protection circuit 10 responds to the first voltage by turning on a current path from the third terminal S3 of the reversed power supply protection circuit 10 to the first terminal S1 of the reversed power supply protection circuit 10, thereby providing current to the first terminal of the first switch transistor Q1 to drive the first switch transistor Q1 to turn on. Thus, a current (referred to as reverse current) from the first ground SGND to the input voltage bus VBB does not pass through the body diode of the first switch transistor Q1, but primarily flows through the channel of the first switch transistor Q1 when the first switch transistor Q1 is in the conductive state. Since the equivalent resistance of the first switch transistor Q1 when it is turned on is very small, the heat generated on the first switch transistor Q1 when carrying the reverse current may be minimal. Thus, protection is provided to the first switch transistor Q1 during reverse connection of the power supply, which reduces the risk of damage to the first switch transistor Q1 (i.e., the high-side switch).

In related technology without the reversed power supply protection circuit 10, when the power supply is connected in reverse, the reverse current would flow through the body diode of the first switch transistor Q1. Moreover, since the internal resistance of the load can be very small, the body diode of the first switch transistor Q1 may have a forward voltage drop of at least 0.7V, which may result in significant power loss across the body diode of the first switch transistor Q1. Excessive power loss can cause the first switch transistor Q1 to overheat and become damaged. Therefore, compared to the related technology, the embodiments of the present application significantly reduce the risk of damage to the first switch transistor Q1 by adding the reversed power supply protection circuit 10.

The power supply is a device that provides electrical energy. In one embodiment, the power supply may be a battery.

Additionally, in the embodiments of the present application, when the positive terminal of the power supply is connected to the input voltage bus VBB and the negative terminal of the power supply is connected to the first ground SGND, indicating a normal power supply connection, the reversed power supply protection circuit 10 can disconnect the current path, specifically, the current path between the third terminal S3 of the reversed power supply protection circuit 10 and the first terminal S1 of the reversed power supply protection circuit 10, so that during the normal power supply connection, the reversed power supply protection circuit 10 does not affect the normal operation of the first switch transistor Q1, allowing the first switch transistor Q1 to perform its respective functions normally.

It should be noted that in the embodiments of the present application, each switch transistor (e.g., the first switch transistor Q1) is exemplified as a MOSFET, where the first terminal of each switch transistor corresponds to the gate of the MOSFET, the second terminal corresponds to the source of the MOSFET, and the third terminal corresponds to the drain of the MOSFET.

In addition, each switch transistor may be any controllable switch, such as insulated gate bipolar transistor (IGBT) devices, integrated gate-commutated thyristor (IGCT) devices, gate turn-off thyristor (GTO) devices, silicon-controlled rectifier (SCR) devices, junction field-effect transistor (JFET) devices, and MOS-controlled thyristor (MCT) devices, etc.

In some embodiments, the first voltage may have a linear relationship with the voltage of the power supply.

Specifically, when the positive terminal of the power supply is connected to the first ground SGND and the negative terminal of the power supply is connected to the input voltage bus VBB, the first voltage is generated based on the voltage of the power supply that presents a linear relationship with the first voltage. For instance, the voltage of the power supply may be in direct proportion to the first voltage. In some implementations, the first voltage may equal the voltage of the power supply, which means there is a positive proportional relationship with a ratio of 1 between the two. In other implementations, the first voltage may be obtained by subtracting a predetermined threshold from the voltage of the power supply, establishing a linear relationship with a ratio of 1 and with a difference of a predetermined threshold between the two.

In some embodiments, as shown in FIG. 2, the third terminal of the reversed power supply protection circuit 10 is connected to the first ground SGND, where when the positive terminal of the power supply is connected to the first ground SGND and the negative terminal of the power supply is connected to the input voltage bus VBB, the first voltage equals the voltage of the power supply.

When the power supply is connected in reverse, due to the clamping effect of the body diode Db of the first switch transistor Q1, the voltage at the output terminal VOUT is higher than the voltage of the input voltage bus VBB by a forward voltage drop of the body diode (approximately 0.7V). At this point, by establishing the current path from the third terminal S3 of the reversed power supply protection circuit 10 to the first terminal S1 of the reversed power supply protection circuit 10, the voltage at the positive terminal of the power supply connected to the first ground SGND may be transformed into a voltage controlling the gate of the first switch transistor Q1, which may be used to ensure that the voltage difference with the voltage at the output terminal VOUT exceeds the threshold voltage for turning on the first switch transistor Q1, thereby turning on the first switch transistor Q1 and achieving the purpose of protecting the first switch transistor Q1.

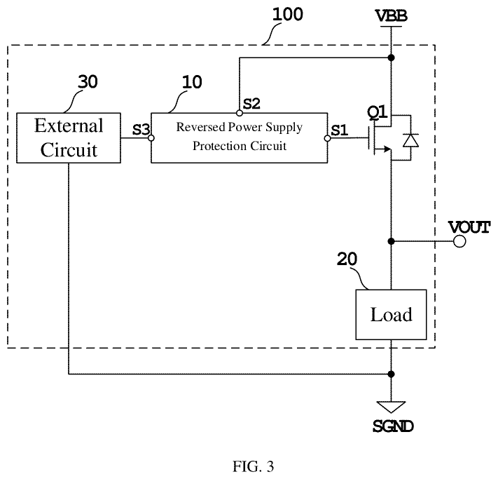

In one embodiment, as shown in FIG. 3, the high-side switch system 100 further comprises an external circuit 30. A first terminal of the external circuit 30 is connected to the third terminal S3 of the reversed power supply protection circuit 10, and a second terminal of the external circuit 30 is connected to the first ground SGND.

As an example, when the positive terminal of the power supply is connected to the first ground SGND and the negative terminal of the power supply is connected to the input voltage bus VBB, indicating a reverse connection of the power supply, the external circuit 30 may output the first voltage to the third terminal S3 of the reversed power supply protection circuit 10 based on the voltage at the positive terminal of the power supply, thereby forming a current path to drive the first switch transistor Q1 to turn on.

When the positive terminal of the power supply is connected to the input voltage bus VBB and the negative terminal of the power supply is connected to the first ground SGND, indicating a normal connection of the power supply, the current path is disconnected, which ensures that the voltage that may be applied by the external circuit 30 to the third terminal S3 of the reversed power supply protection circuit 10 does not affect the normal operation of the first switch transistor Q1, and allows the first switch transistor Q1to perform its respective functions normally.

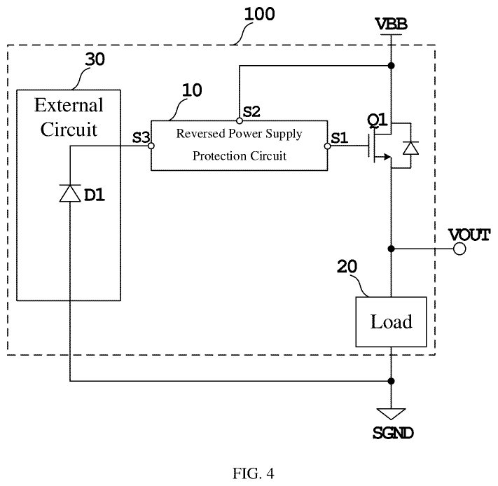

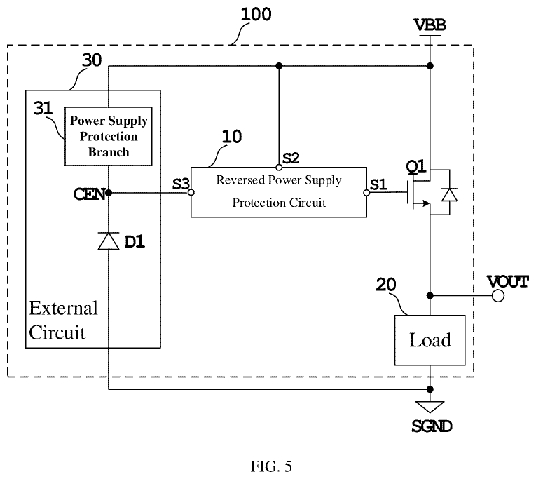

In some embodiments, as shown in FIG. 4, the external circuit 30 may include a first diode D1. The anode of the first diode D1 is connected to the first ground SGND, and the cathode of the first diode D1 is connected to the first terminal of the external circuit 30.

As an example, when the positive terminal of the power supply is connected to the first ground SGND and the negative terminal of the power supply is connected to the input voltage bus VBB, the first voltage equals the difference between the voltage of the power supply and the forward voltage drop of the first diode D1.

In some embodiments, as shown in FIG. 5, the high-side switch system 100 may further include a power supply protection branch 31 in the external circuit 30. The power supply protection branch 31 is connected to the third terminal S3 of the reverse polarity protection branch 10 and the cathode of the first diode D1 at a first node CEN. The power supply protection branch 31 is configured to remain off during the reverse connection of the power supply, in order to isolate the first node CEN from the input voltage bus VBB.

Specifically, in this embodiment of FIG. 5, the external circuit 30 is configured as a controller, such as a microcontroller (MCU), for controlling the first switch transistor Q1. In one embodiment, the controller may have the following three characteristics. First, the controller is connected between the input voltage bus VBB and the first ground SGND. Second, the controller controls the first switch transistor Q1 through high and low voltage levels at the first node CEN. For example, in some embodiments, a high level (such as 5V) may be used to enable/turn on the first switch transistor Q1, and a low level (such as 0V) may be used to turn off the first switch transistor Q1. Third, the first diode D1 is provided between the first and second terminals of the external circuit 30 for electrostatic surge detection (ESD) protection. This ensures that when the power supply is connected in reverse, the voltage at the first node CEN in the external circuit 30 will be lower than the voltage at the positive terminal of the power supply by the forward voltage drop of the first diode D1. This voltage at the first node CEN may be used to control the reversed power supply protection circuit 10, allowing current to flow from the third terminal S3 of the reversed power supply protection circuit 10 to the first terminal S1 of the reversed power supply protection circuit 10, thereby controlling the first switch transistor Q1 to turn on and protect it.

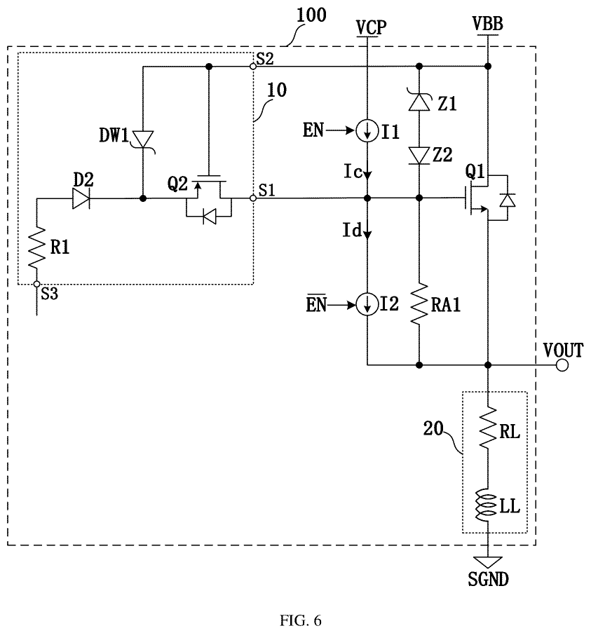

Referring to FIG. 6, FIG. 6 is a diagram of an example circuit structure corresponding to the configuration of the high-side switch system 100 shown in FIG. 1. As shown, the reversed power supply protection circuit 10 comprises a second switch transistor Q2, a first Zener diode DW1, a second diode D2, and a first resistor R1.

The first resistor R1 is connected between the anode of the second diode D2 and the first ground SGND. The cathode of the second diode D2 is connected to the cathode of the first Zener diode DW1 and the second terminal of the second switch transistor Q2. The first terminal of the second switch transistor Q2 and the anode of the first Zener diode DW1 are both connected to the input voltage bus VBB. The third terminal of the second switch transistor Q2 is connected to the first terminal S1 of the reversed power supply protection circuit 10.

In this embodiment, the high-side switch system 100 further comprises a first current source I1, a second current source I2, a fourth Zener diode Z1, a fifth diode Z2, and a ninth resistor RA1.

Specifically, an anode of the fourth Zener diode Z1 and a positive terminal of the first current source I1, as well as a negative terminal of the second current source I2, are connected to the gate of the first switch transistor Q1. A positive terminal of the second current source I2 is connected to the voltage output terminal VOUT. The first current source I1 charges the gate of the first switch transistor Q1 with a current Ic in response to a first logic level of the enable signal EN, to turn on the first switch transistor Q1. The second current source I2 discharges the gate of the first switch transistor Q1 with a current Id in response to the inverse signal EN of the enable signal being at the first logic level (or in response to a second logic level of the enable signal EN) to turn off the first switch transistor Q1. A cathode of the fourth Zener diode Z1 is connected to the input voltage bus VBB. The ninth resistor RA1 is connected between the gate of the first switch transistor Q1 and the voltage output terminal VOUT. A negative terminal of the first current source I1 is connected to a bias voltage VCP, which is generated from the input voltage bus VBB through a bootstrap circuit, and is maintained at a voltage that is higher than the input voltage bus VBB by at least the turn-on threshold voltage of the first switch transistor Q1.

In an example, the first current source I1 provides pull-up current to the first switch transistor Q1 during its normal operation, which turns on the first switch transistor Q1. The second current source I2 provides pull-down current to the first switch transistor Q1 during its normal operation, which turns off the first switch transistor Q1. The ninth resistor RA1 serves as a pull-down resistor. The clamp circuit composed of the fourth Zener diode Z1 and the fifth diode Z2 protects the first switch transistor Q1 from over voltage by clamping the voltage difference between the gate and drain of the first switch transistor Q1.

In an example, the power supply is connected in reverse, i.e., the negative terminal of the power supply is connected to the input voltage bus VBB and the positive terminal of the power supply is connected to the first ground SGND, and the first voltage is applied to the third terminal S3 of the reversed power supply protection circuit 10. In this case, the first voltage is applied across a path including the first resistor R1, the second diode D2, and the first Zener diode DW1. The second diode D2 is forward-biased, and the first Zener diode DW1 provides clamping protection to the voltage applied between the source and gate of the second switch transistor Q2. In response to the source-gate voltage applied to the second switch transistor Q2 (i.e., the voltage difference between the source and gate of the second switch transistor Q2), the second switch transistor Q2 turns on, and correspondingly, a current path conducts from the third terminal S3 to the first terminal S1 of the reversed power supply protection circuit 10. The voltage at the first ground SGND is applied to the gate of the first switch transistor Q1 through the first resistor R1, the second diode D2, and the second switch transistor Q2. At this time, due to the clamping effect of the body diode of the first switch transistor Q1, the voltage at the source of the first switch transistor Q1 (i.e., at the voltage output terminal VOUT) is the voltage on the input voltage bus VBB plus the forward voltage drop of the body diode (approximately 0.7V) of the first switch transistor Q1. Therefore, by setting the clamping voltage of the first Zener diode DW1 high enough, the gate-source voltage of the first switch transistor Q1 can be made sufficient to turn on the first switch transistor Q1, so as to achieve current diversion from the body diode, thereby reducing the heat generated on the first switch transistor Q1 and protecting the first switch transistor Q1.

It can be understood that in the circuit structures of FIG. 6 and subsequent figures of this application, the third terminal S3 of the reversed power supply protection circuit 10 may be connected to the first ground SGND as shown in FIG. 2 as an example, or may be connected to the cathode of the first diode D1 as shown in FIG. 4 as an example. When the third terminal S3 of the reversed power supply protection circuit 10 is connected to the first ground SGND, the first voltage is the voltage difference between the first ground SGND and the input voltage bus VBB (i.e., the voltage of the power supply). When the third terminal S3 of the reversed power supply protection circuit 10 is connected to the cathode of the first diode D1 as shown in FIG. 4, the first voltage is the voltage difference between the first ground SGND and the input voltage bus VBB (i.e., the voltage of the power supply) minus the forward voltage drop of the first diode D1.

When the power supply is connected correctly, i.e., the positive terminal of the power supply is connected to the input voltage bus VBB and the negative terminal of the power supply is connected to the first ground SGND, there may be two cases in analysis. The first case is when the first switch transistor Q1 has been turned on by the first current source I1. In this case, the gate voltage of the first switch transistor Q1 is the bias voltage VCP, which is greater than the voltage on the input voltage bus VBB by at least a threshold voltage of the first switch transistor Q1 (the threshold voltage is the minimum voltage required between the gate and source of the first switch transistor Q1 to form a channel and allow current to flow from source to drain of the first switch transistor Q1). At this time, the source voltage of the second switch transistor Q2 is greater than the gate voltage of the second switch transistor Q2, and consequently, the second switch transistor Q2 turns on. However, since the first ground SGND is connected to the negative terminal of the power supply, the second diode D2 is reverse-biased, thereby cutting off the current path from the first terminal S1 to the third terminal S3 of the reversed power supply protection circuit 10. The second case is when the first switch transistor Q1 has been turned off by the second current source I2. In this case, the gate voltage of the first switch transistor Q1 is the voltage at the voltage output terminal VOUT, the second switch transistor Q2 is turned off, and similarly, the current path from the third terminal S3 to the first terminal S1 of the reversed power supply protection circuit 10 is also cut off.

In general, the high-side switch system 100 shown in FIG. 6 implements control to turn on the first switch transistor Q1 when the power supply is connected in reverse, so as to prevent the first switch transistor Q1 from being damaged due to overheating, while ensuring that the first switch transistor Q1 functions normally when the power supply is connected correctly, i.e., the configuration of the high-side switch system 100 shown in FIG. 6 does not affect the ability of the first switch transistor Q1 to be turned on by the first current source I1 or to be turned off by the second current source I2.

In this embodiment, the load 20 may be an inductive load (which is equivalent to a resistor RL and an inductor LL connected in series), and the voltage output terminal VOUT is connected to the inductive load. In other embodiments, the voltage output terminal VOUT may also be connected to other types of loads, and this application does not impose specific restrictions on this.

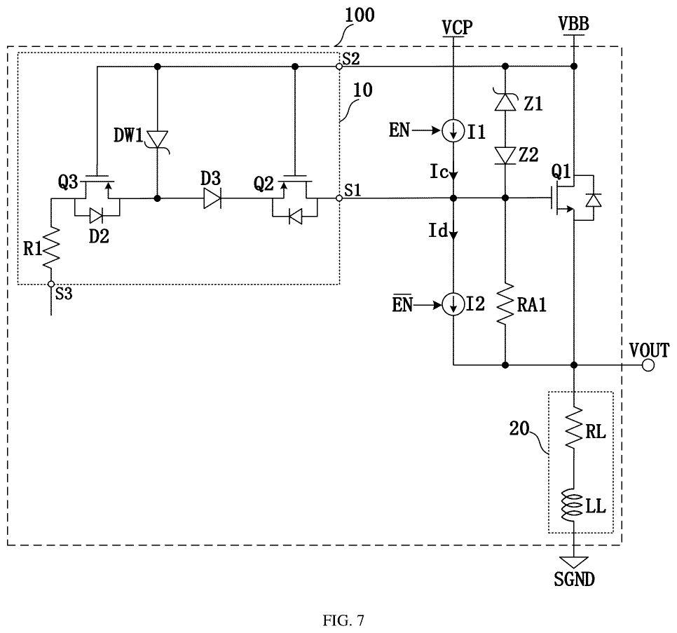

In one embodiment, as shown in FIG. 7, the reversed power supply protection circuit 10 may further include a third switch transistor Q3 and a third diode D3 coupled between the cathode of the first Zener diode DW1 and the second terminal of the second switch transistor Q2, where the second diode D2 is a body diode of the third switch transistor Q3. The embodiment of FIG. 7 is based on the circuit structure of FIG. 6, with the third switch transistor Q3 and the third diode D3 added. A first terminal of the third switch transistor Q3 is connected to the input voltage bus VBB. A second terminal of the third switch transistor Q3 is connected to the cathode of the first Zener diode DW1 and an anode of the third diode D3, a third terminal of the third switch transistor Q3 is connected to the first resistor R1, and a cathode of the third diode D3 is connected to the second terminal of the second switch transistor Q2.

In this embodiment, the second diode D2 is implemented by the body diode of the third switch transistor Q3. When the power supply is connected correctly and the first switch transistor Q1 is driven to be turned on by the first current source, the third diode D3 may be added to prevent the gate voltage (i.e., the bias voltage VCP) of the first switch transistor Q1 from being reversely fed to the third terminal S3 of the reversed power supply protection circuit 10 from the first terminal S1 of the reversed power supply protection circuit 10 through conduction of the body diode of the second switch transistor Q2 and the turned-on third switch transistor Q3.

In the embodiment of FIG. 7, the operation mechanism of the reversed power supply protection circuit 10 is as follows. When the power supply is connected in reverse, as described earlier, the second switch transistor Q2 is turned on due to the gate-source voltage applied to it, allowing current to flow from the third terminal S3 to the first terminal S1 of the reversed power supply protection circuit 10. At this time, the third switch transistor Q3 is also turned on, conducting current from the anode to the cathode of the third diode D3, effectively protecting the second switch transistor Q2 and providing an alternative current path for the reversed power supply protection circuit 10. In other scenarios, when the power supply is connected correctly, the second switch transistor Q2 remains off, and the third switch transistor Q3 also turns off, preventing current from flowing through the third diode D3.

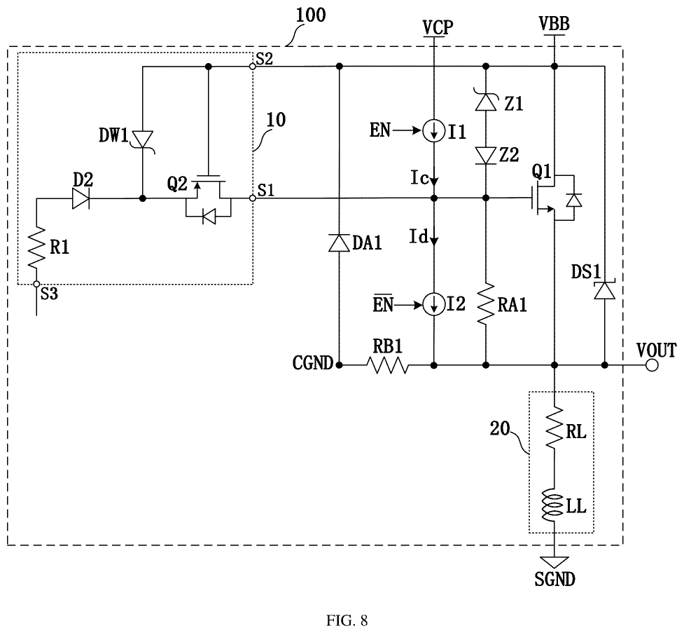

In some embodiments, the first switch transistor Q1 and the reversed power supply protection circuit 10 may be integrated within the same integrated circuit chip, with the substrate of the integrated circuit chip serving as a second ground CGND (or chip ground), as shown in FIG. 8 as an example.

Furthermore, there may exist a parasitic resistance between the second ground CGND and the voltage output terminal VOUT, as well as a parasitic diode between the input voltage bus VBB and the second ground CGND.

In an example, as illustrated in FIG. 8, a resistor RB1 represents the parasitic resistance between the second ground CGND and the voltage output terminal VOUT. Due to existence of this resistance, the second ground CGND and the voltage output terminal VOUT may be regarded as approximately open-circuited. Diode DA1 is the parasitic diode between the input voltage bus VBB and the second ground CGND.

The diode DA1 represents a parasitic PN junction between an N-type isolation ring in the integrated circuit chip and the P-type substrate (P-SUB). Most N-type isolation rings may be connected to the highest potential/voltage within the integrated circuit chip, namely, the input voltage bus VBB. In this configuration, when the power supply is connected in reverse, a small current may be generated flowing from the second ground CGND through the forward-biased diode DA1 to the input voltage bus VBB. However, devices within the reversed power supply protection circuit 10, such as the second switch transistor Q2, may include an N-type doped region that can form a parasitic NPN transistor with the diode DA1 (e.g., the N-type isolation ring serves as the emitter, the P-type substrate as the base, and the N-type doped region as the collector). When the diode DA1 is forward-biased, the emitter junction of the parasitic NPN transistor conducts, resulting in a large current flowing from the collector to the emitter, that is, from the N-type doped region of the second switch transistor Q2 to the input voltage bus VBB. Since the N-type doped region of the second switch transistor Q2 is the source terminal located between the first terminal S1 and the third terminal S3 of the reversed power supply protection circuit 10, the current flowing from the N-type doped region of Q2 to the input voltage bus VBB diverts the current flowing from the third terminal S3 to the first terminal S1 of the reversed power supply protection circuit 10, producing a significant voltage drop across the first resistor R1. This results in an insufficient voltage delivered to the gate of the first switch transistor Q1, which is not able to turn on the first switch transistor Q1. In summary, as the current flowing through the body diode of the first switch transistor Q1 increases, the current through diode DA1 also increases with the rising voltage at the first ground CGND, leading to more current being siphoned from the gate of the first switch transistor Q1, and causing the first switch transistor Q1to remain off in power supply reverse connection scenarios.

Embodiments provided in this application provide three solutions to the problem of parasitic NPN transistor conducting in the power supply reverse connection scenarios. The first solution, as shown in FIG. 8, comprises a first Schottky diode DS1 in the high-side switch system 100. In this embodiment, the first Schottky diode DS1 is added to the circuit shown in FIG. 6.

Specifically, the anode of the first Schottky diode DS1 is connected to the voltage output terminal VOUT of the high-side switch system 100, and its cathode is connected to the input voltage bus VBB.

Since the forward voltage drop of the first Schottky diode DS1 is lower than that of the diode DA1, more current from the voltage output terminal VOUT to the input voltage bus VBB flows through the first Schottky diode DS1, reducing the current injected into the N-type isolation ring of the first switch transistor Q1, preventing an increase in current through the diode DA1 and thereby avoiding the siphoning of current from the gate of the first switch transistor Q1. Consequently, the first switch transistor Q1 can turn on in the reversed power supply connection scenarios.

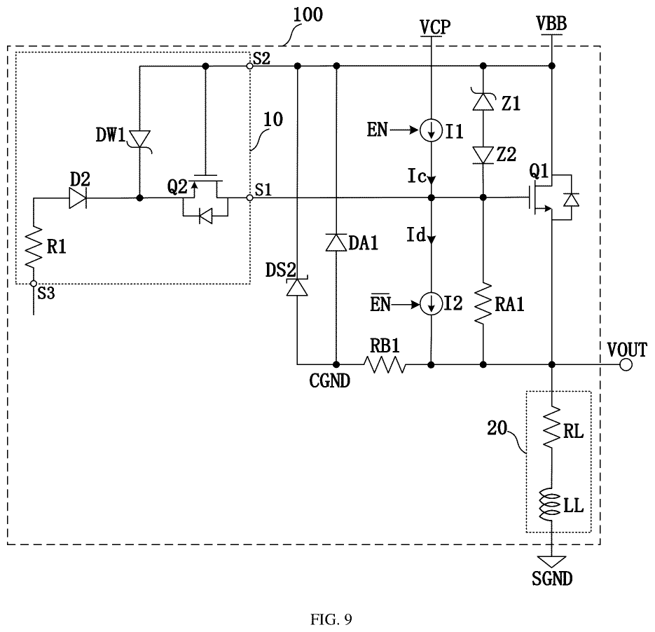

The second solution, as illustrated in FIG. 9, introduces a second Schottky diode DS2 into the high-side switch system 100. In this embodiment, the second Schottky diode DS2 is added to the circuit shown in FIG. 6.

The anode of the second Schottky diode DS2 is connected to the second ground CGND, and its cathode is connected to the input voltage bus VBB.

Specifically, the forward voltage drop of the second Schottky diode DS2 is approximately 0.3V, which is lower than that of the diode DA1. This configuration allows the second Schottky diode DS2 to turn on before the diode DA1 in the reversed power supply connection scenarios, ensuring that the majority of current flows through the second Schottky diode DS2 to the input voltage bus VBB. This effectively prevents the conduction of the parasitic NPN transistor formed between the input voltage bus VBB, the second ground CGND, and the source terminal of the second switch transistor Q2, thereby avoiding the siphoning of current from the gate of the first switch transistor Q1, and enabling the first switch transistor Q1 to successfully turn on. Additionally, when the power supply is correctly connected, the second Schottky diode DS2 remains reverse-biased, without affecting the functionality of the high-side switch system 100.

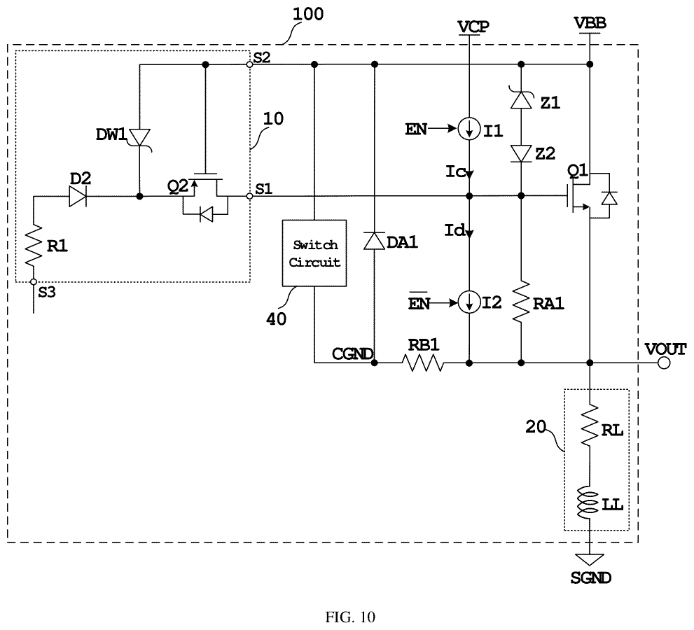

The third solution, as illustrated in FIG. 10, comprises a switch circuit 40 connected between the input voltage bus VBB and the second ground CGND. In this embodiment, the switch circuit 40 is added to the circuit shown in FIG. 6.

The switch circuit 40 is configured to turn on when the positive terminal of the power supply is connected to the first ground SGND, and the negative terminal of the power supply is connected to the input voltage bus VBB, shorting the input voltage bus VBB to the second ground CGND. This prevents current from flowing through the diode DA1, thereby preventing conduction of the parasitic NPN transistor formed by the input voltage bus VBB, the second ground CGND, and the source terminal of the second switch transistor Q2, which ensures that the first switch transistor Q1 be successfully turned on in the reversed power supply connection scenarios.

The switch circuit 40 is also designed to turn off when the positive terminal of the power supply is connected to the input voltage bus VBB and the negative terminal of the power supply is connected to the first ground SGND, thereby stopping the shorting of the input voltage bus VBB to the second ground CGND, without affecting the functionality of the high-side switch system 100.

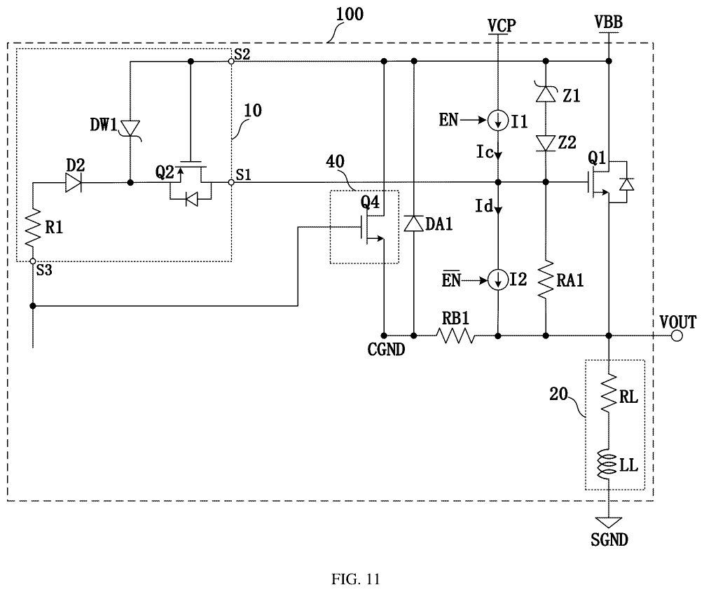

In one embodiment, as shown in FIG. 11, the switch circuit 40 may include a fourth switch transistor Q4.

A first terminal of the fourth switch transistor Q4 is connected to the third terminal S3 of the reversed power supply protection circuit 10. A third terminal of the fourth switch transistor Q4 is connected to the input voltage bus VBB, and a second terminal of the fourth switch transistor Q4 is connected to the second ground CGND.

Specifically, when the positive terminal of the power supply is connected to the first ground SGND and the negative terminal of the power supply is connected to the input voltage bus VBB, the first voltage is simultaneously applied to the third terminal S3 of the reversed power supply protection circuit 10 and the gate terminal of the fourth switch transistor Q4, thereby turning on the fourth switch transistor Q4. As a result, most current flows through the fourth switch transistor Q4 to the input voltage bus VBB. This effectively prevents the conduction of the parasitic NPN transistor formed by the input voltage bus VBB, the second ground CGND, and the source terminal of the second switch transistor Q2, enabling the first switch transistor Q1 to successfully turn on.

When the power supply is correctly connected, the first voltage is no longer applied to the first terminal of the fourth switch transistor Q4, and the fourth switch transistor Q4 remains off, and does not affect the functionality of the high-side switch system 100.

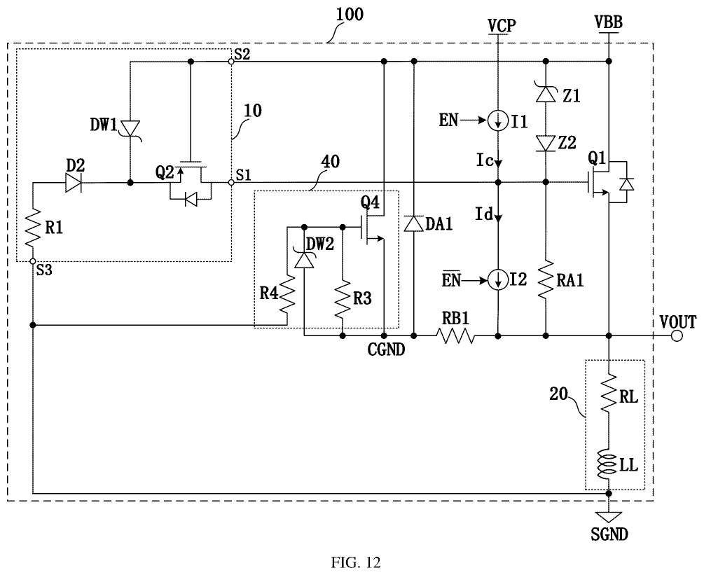

In one embodiment, as shown in FIG. 12, the switch circuit 40 may further comprise a second Zener diode DW2, a third resistor R3, and a fourth resistor R4.

An anode of the second Zener diode DW2 and a first terminal of the third resistor R3 are both connected to the second ground CGND, and a cathode of the second Zener diode DW2 is connected to a second terminal of the third resistor R3, a first terminal of the fourth resistor R4 and the first terminal of the fourth switch transistor Q4, respectively. A second terminal of the fourth resistor R4 is connected to the third terminal S3 of the reversed power supply protection circuit 10. This embodiment exemplifies the connection of the third terminal S3 of the reversed power supply protection circuit 10 to the first ground SGND.

Specifically, when the power supply is connected in reverse, the diode DA1 conducts and clamps the second ground CGND to approximately 0.7V (the forward voltage drop of the diode DA1). Simultaneously, the second Zener diode DW2 clamps the voltage input from the power supply's positive terminal through the first ground SGND to the gate of the fourth switch transistor Q4. The fourth switch transistor Q4 turns on, shorting the diode DA1. At this point, most current flows through the fourth switch transistor Q4 to the input voltage bus VBB. This effectively prevents the conduction of the parasitic NPN transistor formed by the input voltage bus VBB, the second ground CGND, and the source terminal of the second switch transistor Q2, which allows the first switch transistor Q1 to successfully turn on.

When the power supply is correctly connected, the third resistor R3 acts as a pull-down resistor, keeping the fourth switch transistor Q4 turned off and thus not affecting the functionality of the high-side switch system 100.

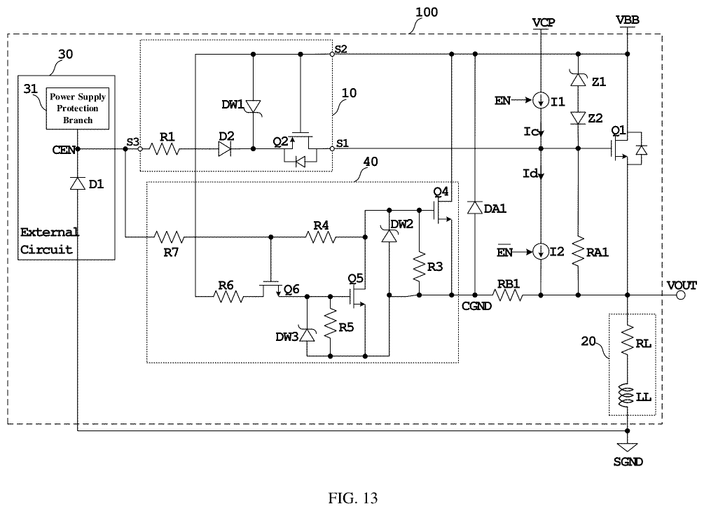

In one embodiment, the third terminal S3 of the reversed power supply protection circuit 10 may be connected as shown in FIG. 5, and as depicted in FIG. 13, the switch circuit 40 may further comprise a fifth switch transistor Q5, a sixth switch transistor Q6, a third Zener diode DW3, a fifth resistor R5, a sixth resistor R6, and a seventh resistor R7. The fourth resistor R4 is connected to the third terminal S3 of the reversed power supply protection circuit 10 through the seventh resistor R7.

A third terminal of the fifth switch transistor Q5 is connected to the first terminal of the fourth resistor R4 and the first terminal of the fourth switch transistor Q4. A second terminal of the fifth switch transistor Q5, a first terminal of the fifth resistor R5, and an anode of the third Zener diode DW3 are all connected to the second ground CGND. A cathode of the third Zener diode DW3 is connected to a second terminal of the fifth resistor R5, a second terminal of the sixth switch transistor Q6, and a first terminal of the fifth switch transistor Q5. A first terminal of the sixth switch transistor Q6 is connected to the second terminal of the fourth resistor R4 and a second terminal of the seventh resistor R7. A third terminal of the sixth switch transistor Q6 is connected to a second terminal of the sixth resistor R6. A first terminal of the seventh resistor R7 is connected to the third terminal S3 of the reversed power supply protection circuit 10, and a first terminal of the sixth resistor R6 is connected to the input voltage bus VBB.

Specifically, when the power supply is connected in reverse, the diode DA1 conducts and clamps the second ground CGND to approximately 0.7V. The voltage at the first node CEN is the difference between the voltage at the positive terminal of the power supply and the forward voltage drop of the first diode D2. The voltage at the first node CEN is applied to the gate of the fourth switch transistor Q4 through the seventh resistor R7 and the fourth resistor R4, turning on the fourth switch transistor Q4, which short-circuits the diode DA1. At this point, most of the current flows from the second ground CGND through the fourth switch transistor Q4 to the input voltage bus VBB. This effectively prevents the conduction of the parasitic NPN transistor formed by the input voltage bus VBB, the second ground CGND, and the source terminal of the second switch transistor Q2, allowing the first switch transistor Q1 to successfully turn on, and the fifth switch transistor Q5 and the sixth switch transistor Q6 to remain off.

When the power supply is connected correctly, if the first node CEN is at a logic low level, the third resistor R3 acts as a pull-down resistor, keeping the third switch transistor Q3 off, ensuring that the switch circuit 40 does not affect the functionality of the high-side switch system 100. If the first node CEN is at a logic high level, the sixth switch transistor Q6 turns on, allowing the voltage of the input voltage bus VBB to be applied through the sixth switch transistor Q6 to the cathode of the third Zener diode DW3, and clamped by the third Zener diode DW3. The fifth switch transistor Q5 turns on, pulling down the gate voltage of the fourth switch transistor Q4. Notably, the current that pulls up the gate of the fourth switch transistor Q4 through the seventh resistor R7 and the fourth resistor R4 when the first node CEN is at a logic high level is much smaller than the current that pulls down the gate of the fourth switch transistor Q4 when the fifth switch transistor Q5 is on. Thus, the fourth switch transistor Q4 can turn off, preventing the switch circuit 40 from affecting the functionality of the high-side switch system 100.

It should be noted that the switch circuit 40 shown in FIG. 13 may also be applied in scenarios where the third terminal S3 of the reversed power supply protection circuit 10 is connected to the first ground SGND, as illustrated in FIGS. 2-4, and the working principle is similar to those described above with respect to FIG. 13.

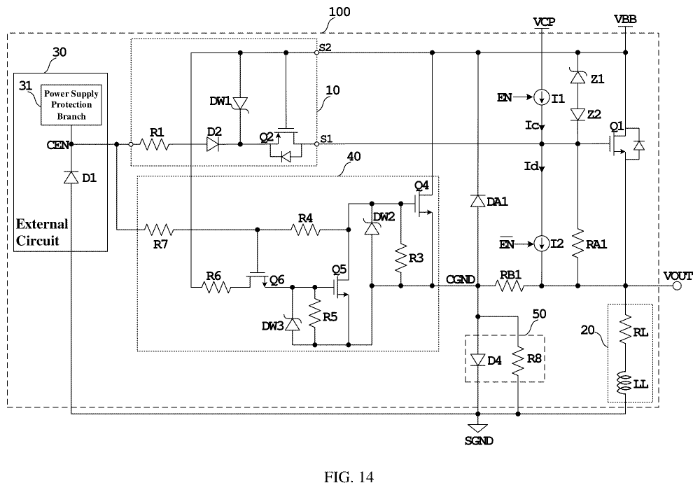

In one embodiment, as illustrated in FIG. 14, the high-side switch system 100 may further comprise a ground network 50, with a first terminal of the ground network 50 connected to the first ground SGND and a second terminal of the ground network 50 connected to the second ground CGND.

The ground network 50 includes a fourth diode D4 and an eighth resistor R8, with a cathode of the fourth diode D4 and a first terminal of the eighth resistor R8 both connected to the first terminal of the ground network 50, and an anode of the fourth diode D4 and a second terminal of the eighth resistor R8 connect to the second terminal of the ground network 50.

Specifically, when the power supply is connected in reverse, the presence of the fourth diode D4 prevents reverse current from flowing from the first ground SGND to the input voltage bus VBB. At the same time, the eighth resistor R8 effectively limits the reverse current flowing from the first SGND to the input voltage bus VBB, thus protecting the integrated circuit chip (i.e., the first switch transistor Q1 and an integrated circuit chip where the reversed power supply protection circuit 10 resides).

It is understood that FIG. 14 illustrates an embodiment where the ground network 50 is added to the circuit structure shown in FIG. 13. Other embodiments, such as those described with respect to FIGS. 8-12, may also incorporate the ground network 50 connected between the first ground SGND and the second ground CGND, and the working principle of the ground network 50 is similar to those described with respect to FIG. 14.

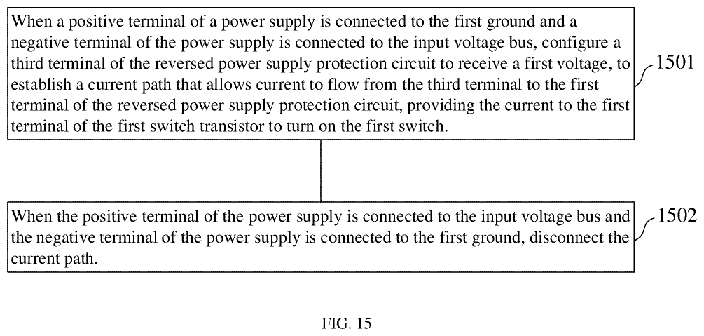

Referring to FIG. 15, FIG. 15 is a flowchart of a control method for a high-side switch system provided by an embodiment of this application. The high-side switch system comprises a first switch transistor connected between an input voltage bus and a voltage output terminal of the high-side switch system, a load connected between the voltage output terminal of the high-side switch system and a first ground, and a reversed power supply protection circuit. A first terminal of the reversed power supply protection circuit is connected to a first terminal of the first switch transistor, and a second terminal of the reversed power supply protection circuit is connected to the input voltage bus. In some embodiments, the high-side switch system may be implemented through a circuit shown in any one of FIGS. 1-14, and the specific implementation process has been detailed in the aforementioned embodiments and will not be repeated herein. As shown in FIG. 15, the control method of the high-side switch system comprises the following steps:
Step 1501: When a positive terminal of a power supply is connected to the first ground and a negative terminal of the power supply is connected to the input voltage bus, configure a third terminal of the reversed power supply protection circuit to receive a first voltage, to establish a current path that allows current to flow from the third terminal of the reversed power supply protection circuit to the first terminal of the reversed power supply protection circuit, providing current to the first terminal of the first switch transistor to turn on the first switch.
Step 1502: When the positive terminal of the power supply is connected to the input voltage bus and the negative terminal of the power supply is connected to the first ground, disconnect the current path.

In one embodiment, the third terminal of the reversed power supply protection circuit is connected to the first ground.

Specifically, when the positive terminal of the power supply is connected to the first ground and the negative terminal of the power supply is connected to the input voltage bus, the first voltage equals the voltage of the power supply.

In some embodiments, the high-side switch system further comprises an external circuit, with a first terminal of the external circuit connected to the third terminal of the reversed power supply protection circuit and a second terminal of the external circuit connected to the first ground. The external circuit comprises a first diode, with the anode connected to the first ground and the cathode connected to the first terminal of the external circuit.

When the positive terminal of the power supply is connected to the first ground and the negative terminal of the power supply is connected to the input voltage bus, the first voltage equals the difference between the power supply voltage and the forward conduction voltage drop of the first diode.

In some embodiments, the first switch transistor and the reversed power supply protection circuit are integrated within the same integrated circuit chip, with the substrate of the integrated circuit chip serving as a second ground. The high-side switch system further comprises a ground network and a switch circuit, with the ground network connected between the first ground and the second ground, and the switch circuit connected between the input voltage bus and the second ground. The ground network includes a fourth diode and a second resistor, with the cathode of the fourth diode and a first terminal of the second resistor both connected to the first ground, and the anode of the fourth diode and a second terminal of the second resistor connect to the second ground. The control method of the high-side switch system further comprises the following steps: when the positive terminal of the power supply is connected to the first ground and the negative terminal of the power supply is connected to the input voltage bus, turning on the switch circuit to short-circuit the input voltage bus to the second ground. When the positive terminal of the power supply is connected to the input voltage bus and the negative terminal of the power supply is connected to the first ground, turn off the switch circuit.

For details of specific control of the high-side switch system and beneficial effects of the embodiment method, reference may be made to the relevant descriptions provided with respect to the above high-side switch system embodiments, and the details are not repeated herein for brevity.

Embodiments of the present application also provide an integrated circuit chip that comprises the first switch transistor Q1 and the reversed power supply protection circuit 10 in any embodiment of the high-side switch system 100 as described above.

Embodiments of the present application further provides an electronic device that includes an integrated circuit chip in any embodiment of this application as described above.

The above descriptions are merely some embodiments of this application and are not intended to limit the scope of the claims. Any equivalent structures or processes derived from the contents of this application and its accompanying drawings, or direct or indirect applications in other related technical fields, are similarly included within the patent protection scope of this application.

The above embodiments are intended to illustrate the technical solutions of this application, not to limit them; under the conceptual framework of this application, the technical features of the above embodiments or different embodiments may be combined, and the steps may be executed in any applicable order. A person skilled in the art should understand that modifications or equivalent substitutions can be made to the technical solutions described in the various embodiments without departing from the essence of the corresponding technical solutions covered by this application.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A high-side switch system, comprising:
a first switch transistor, a load, a reversed power supply protection circuit, and an input voltage bus, wherein:
a first terminal of the first switch transistor is connected to a first terminal of the reversed power supply protection circuit;
a second terminal of the first switch transistor is connected to a first terminal of the load at a voltage output terminal of the high-side switch system;
a third terminal of the first switch transistor and a second terminal of the reversed power supply protection circuit are connected to the input voltage bus; and
a second terminal of the load is connected to a first ground;
wherein the reversed power supply protection circuit is configured to:
when a positive terminal of a power supply is connected to the first ground and a negative terminal of the power supply is connected to the input voltage bus,
receive a first voltage at a third terminal of the reversed power supply protection circuit; and
in response to the first voltage, establish a current path from the third terminal to the first terminal of the reversed power supply protection circuit, to provide current to the first terminal of the first switch; and
wherein the reversed power supply protection circuit is further configured to disconnect the current path when the positive terminal of the power supply is connected to the input voltage bus and the negative terminal of the power supply is connected to the first ground.

2. The high-side switch system according to claim 1, wherein the third terminal of the reversed power supply protection circuit is connected to the first ground, and
when the positive terminal of the power supply is connected to the first ground and the negative terminal of the power supply is connected to the input voltage bus, the first voltage equals a voltage of the power supply.

3. The high-side switch system according to claim 1, further comprising:
an external circuit, including a first terminal connected to the third terminal of the reversed power supply protection circuit and a second terminal connected to the first ground;
wherein the external circuit is configured to output the first voltage to the third terminal of the reversed power supply protection circuit based on a voltage of the power supply when the positive terminal of the power supply is connected to the first ground and the negative terminal of the power supply is connected to the input voltage bus.

4. The high-side switch system according to claim 3, wherein the external circuit comprises a first diode, an anode of the first diode is connected to the first ground, and a cathode of the first diode is connected to the first terminal of the external circuit; and
wherein, when the positive terminal of the power supply is connected to the first ground and the negative terminal of the power supply is connected to the input voltage bus, the first voltage equals a difference between the voltage of the power supply and a forward voltage drop of the first diode.

5. The high-side switch system according to claim 1, wherein the reversed power supply protection circuit comprises a second switch transistor, a first Zener diode, a second diode, and a first resistor; and
wherein the first resistor is connected between an anode of the second diode and the first ground, and a cathode of the second diode is connected to a cathode of the first Zener diode and a second terminal of the second switch transistor,
a first terminal of the second switch transistor and an anode of the first Zener diode are connected to the input voltage bus, and
a third terminal of the second switch transistor is connected to the first terminal of the reversed power supply protection circuit.

6. The high-side switch system according to claim 5, wherein the reversed power supply protection circuit further comprises:
a third switch transistor, wherein the second diode is a body diode of the third switch transistor; and
a third diode connected between the cathode of the first Zener diode and the second terminal of the second switch transistor; and
wherein a first terminal of the third switch transistor is connected to the input voltage bus, a second terminal of the third switch transistor is connected to the cathode of the first Zener diode and an anode of the third diode, a third terminal of the third switch transistor is connected to the first resistor, and a cathode of the third diode is connected to the second terminal of the second switch transistor.

7. The high-side switch system according to claim 1, wherein the first switch transistor and the reversed power supply protection circuit are integrated within a single integrated circuit chip, and a substrate of the integrated circuit chip is connected to a second ground.

8. The high-side switch system according to claim 7, further comprising:
a first Schottky diode, wherein an anode of the first Schottky diode is connected to the voltage output terminal of the high-side switch system, and a cathode of the first Schottky diode is connected to the input voltage bus.

9. The high-side switch system according to claim 7, further comprising:
a second Schottky diode, wherein an anode of the second Schottky diode is connected to the second ground, and a cathode of the second Schottky diode is connected to the input voltage bus.

10. The high-side switch system according to claim 7, further comprising:
a switch circuit, connected between the input voltage bus and the second ground, and configured to:
turn on when the positive terminal of the power supply is connected to the first ground and the negative terminal of the power supply is connected to the input voltage bus, to short the input voltage bus to the second ground; and
turn off when the positive terminal of the power supply is connected to the input voltage bus and the negative terminal of the power supply is connected to the first ground, to stop shorting the input voltage bus to the second ground.

11. The high-side switch system according to claim 10, wherein the switch circuit comprises a fourth switch transistor,
a first terminal of the fourth switch transistor is connected to the third terminal of the reversed power supply protection circuit, a second terminal of the fourth switch transistor is connected to the second ground, and a third terminal of the fourth switch transistor is connected to the input voltage bus,.

12. The high-side switch system according to claim 11, wherein the switch circuit further comprises a second Zener diode, a third resistor, and a fourth resistor; and
wherein an anode of the second Zener diode and a first terminal of the third resistor are connected to the second ground;
a cathode of the second Zener diode is connected to a second terminal of the third resistor, a first terminal of the fourth resistor, and the first terminal of the fourth switch transistor; and
the second terminal of the fourth resistor is connected to the third terminal of the reversed power supply protection circuit.

13. The high-side switch system according to claim 12, wherein the switch circuit further comprises a fifth switch transistor, a sixth switch transistor, a third Zener diode, a fifth resistor, a sixth resistor, and a seventh resistor;
wherein a third terminal of the fifth switch transistor is connected to the first terminal of the fourth resistor and the first terminal of the fourth switch transistor;
a second terminal of the fifth switch transistor, a first terminal of the fifth resistor, and an anode of the third Zener diode are connected to the second ground;
a cathode of the third Zener diode is connected to a second terminal of the fifth resistor, a second terminal of the sixth switch transistor, and a first terminal of the fifth switch transistor;
a first terminal of the sixth switch transistor is connected to the second terminal of the fourth resistor and a second terminal of the seventh resistor;
a third terminal of the sixth switch transistor is connected to a second terminal of the sixth resistor;
a first terminal of the seventh resistor is connected to the third terminal of the reversed power supply protection circuit; and
a first terminal of the sixth resistor is connected to the input voltage bus.

14. The high-side switch system according to claim 7, further comprising:
a grounding network comprising a first terminal connected to the first ground and a second terminal connected to the second ground;
wherein the grounding network comprises a fourth diode and an eighth resistor, a cathode of the fourth diode and a first terminal of the eighth resistor are connected to the first terminal of the grounding network, and an anode of the fourth diode and a second terminal of the eighth resistor are connected to the second terminal of the grounding network.

15. A method of controlling a high-side switch system,
wherein the high-side switch system comprises: a first switch transistor connected between an input voltage bus and a voltage output terminal of the high-side switch system; a load connected between the voltage output terminal and a first ground; and a reversed power supply protection circuit, wherein a first terminal of the reversed power supply protection circuit is connected to a first terminal of the first switch transistor, and a second terminal of the reversed power supply protection circuit is connected to the input voltage bus; and
wherein the method comprises:
configuring to receive a first voltage at a third terminal of the reversed power supply protection circuit, to establish a current path from the third terminal to the first terminal of the reversed power supply protection circuit when a positive terminal of a power supply is connected to the first ground and a negative terminal of the power supply is connected to the input voltage bus, wherein the current path provides current to the first terminal of the first switch transistor to turn on the first switch transistor; and
disconnecting the current path when the positive terminal of the power supply is connected to the input voltage bus and the negative terminal of the power supply is connected to the first ground.

16. The method according to claim 15, wherein the third terminal of the reversed power supply protection circuit is connected to the first ground, and when the positive terminal of the power supply is connected to the first ground and the negative terminal of the power supply is connected to the input voltage bus, the first voltage equals a voltage of the power supply.

17. The method according to claim 15, wherein the high-side switch system further comprises an external circuit, a first terminal of the external circuit is connected to the third terminal of the reversed power supply protection circuit, and a second terminal of the external circuit is connected to the first ground;
the external circuit comprises a first diode, an anode of the first diode is connected to the first ground, and a cathode of the first diode is connected to the first terminal of the external circuit; and
when the positive terminal of the power supply is connected to the first ground and the negative terminal of the power supply is connected to the input voltage bus, the first voltage equals a difference between the voltage of the power supply and a forward voltage drop of the first diode.

18. The method according to claim 15, wherein the first switch transistor and the reversed power supply protection circuit are integrated within a single integrated circuit chip, and a substrate of the integrated circuit chip is connected to a second ground;
the high-side switch system further comprises a grounding network and a switch circuit, the grounding network is connected between the first ground and the second ground, and the switch circuit is connected between the input voltage bus and the second ground; and
the grounding network comprises a fourth diode and an eighth resistor, a cathode of the fourth diode and a first terminal of the eighth resistor are connected to the first ground, and an anode of the fourth diode and a second terminal of the eighth resistor are connected to the second ground; and
wherein the method further comprises:
turning on the switch circuit to short the input voltage bus to the second ground when the positive terminal of the power supply is connected to the first ground and the negative terminal of the power supply is connected to the input voltage bus; and
turning off the switch circuit when the positive terminal of the power supply is connected to the input voltage bus and the negative terminal of the power supply is connected to the first ground.

19. An integrated circuit chip, comprising the first switch transistor and the reversed power supply protection circuit of the high-side switch system according to claim 1.

20. An electronic device, comprising the integrated circuit chip according to claim 19.
